(19) United States
(12) Patent Application Publication
(10) Pub. No.: US 2022/0365428 A1
(43) Pub. Date: Nov. 17, 2022

(54) PHOTORESIST MATERIALS AND ASSOCIATED METHODS

(71) Applicant: Taiwan Semiconductor Manufacturing Company, Ltd., Hsinchu (TW)

(72) Inventors: Ming-Hui WENG, New Taipei City (TW); Yahru CHENG, Taipei (TW); Ching-Yu CHANG, Yilang County (TW)

(21) Appl. No.: 17/302,880

(22) Filed: May 14, 2021

(51) Int. Cl. G03F 7/004; H01L 21/027

(52) U.S. Cl. CPC G03F 7/0042; H01L 21/0276; G03F 7/20

(57) ABSTRACT

Photoresist materials described herein may include various types of tin (Sn) clusters having one or more types of ligands. As an example, a photoresist material described herein may include tin clusters bearing two or more different types of carboxylate ligands. As another example, a photoresist material described herein may include tin oxide clusters that include carbonate ligands. The two or more different types of carboxylate ligands and the carbonate ligands may reduce, minimize, and/or prevent crystallization of the photoresist materials described herein, which may increase the coating performance of the photoresist materials and may decrease the surface roughness of photoresist layers formed using the photoresist materials described herein.

### BACKGROUND

As semiconductor device sizes continue to shrink some lithography technologies suffer from optical restrictions, which lead to resolution issues and reduced lithography performance. In comparison, extreme ultraviolet (EUV) lithography can achieve much smaller semiconductor device sizes and/or feature sizes through the use of reflective optics and radiation wavelengths of approximately 13.5 nanometers or less.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2F are diagrams of an example implementation described herein.

FIGS. 3A, 3B, and 4A-4C are diagrams of example photoresist material reactions described herein.

FIG. 5 is a diagram of example components of one or more devices of FIG. 1.

FIG. 6 is a flowchart of an example process relating to forming a pattern in a photoresist layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One of the issues with extreme ultraviolet (EUV) lithography is that EUV radiation is highly absorbed by most matter due to the short wavelength of EUV radiation. As a result, only a small fraction of EUV radiation that is generated by an EUV source is finally available at a substrate that is to be patterned. Thus, elements used in deep ultraviolet lithography photoresist materials (e.g., carbon (C), hydrogen, and oxygen (O), among other examples) may not be suitable for EUV lithography, as these elements may not provide sufficient absorption of EUV radiation. One way of compensating for the loss of EUV radiation intensity at the substrate is to use highly-absorptive metallic photoresist materials. However, these materials may suffer from surface roughness issues and air/water sensitivity, which can decrease the patterning performance of the photoresist layers that are formed using the materials.

Some implementations described herein provide photoresist materials that include various types of tin (Sn) clusters having one or more types of ligands. As an example, a photoresist material described herein may include tin clusters bearing two or more different types of carboxylate ligands. As another example, a photoresist material described herein may include tin oxide clusters that include carbonate ligands. The two or more different types of carboxylate ligands and the carbonate ligands may reduce, minimize, and/or prevent crystallization of the photoresist materials described herein, which may increase the coating performance of the photoresist materials and may decrease the surface roughness of photoresist layers formed using the photoresist materials described herein.

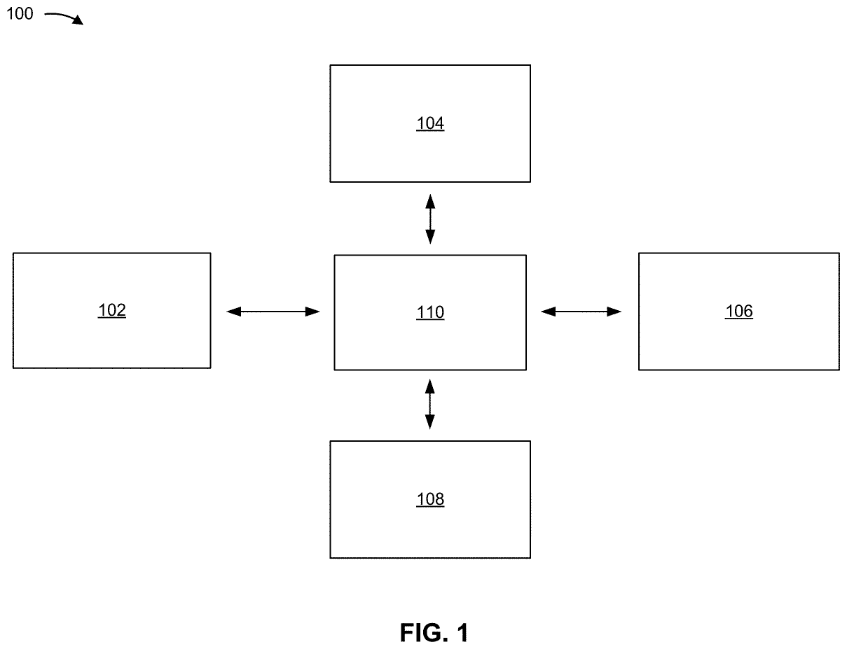

FIG. 1 is a diagram of an example environment 100 in which systems and/or methods described herein may be implemented. As shown in FIG. 1, environment 100 may include a plurality of semiconductor processing tools 102-108 and a wafer/die transport tool 110. The plurality of semiconductor processing tools 102-108 may include a deposition tool 102, an exposure tool 104, a developer tool 106, an etch tool 108, and/or another type of semiconductor processing tool. The tools included in example environment 100 may be included in a semiconductor clean room, a semiconductor foundry, a semiconductor processing and/or manufacturing facility, and/or another type of semiconductor processing environment.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

In some implementations, one or more of the deposition tool 102, the exposure tool 104, and/or the developer tool 106 may be configured to perform various types of baking operations such as a pre-exposure bake operation or a post-exposure bake operation. Baking the substrate may include elevating the temperature of the photoresist layer for a time duration. In some implementations, the deposition tool 102, the exposure tool 104, and the developer tool 106 are included in a track unit designed for multiple photoresist-related processes including coating, baking, and developing.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotopically or directionally etch the one or more portions.

Wafer/die transport tool 110 includes a mobile robot, a robot arm, a tram or rail car, an overhead hoist transport (OHT) system, an automated material handling system (AMHS), and/or another type of device or system that is used to transport wafers and/or dies between semiconductor processing tools 102-108 and/or to and from other locations such as a wafer rack, a storage room. In some implementations, wafer/die transport tool 110 may be a programmed device that is configured to travel a particular path and/or may operate semi-autonomously or autonomously.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

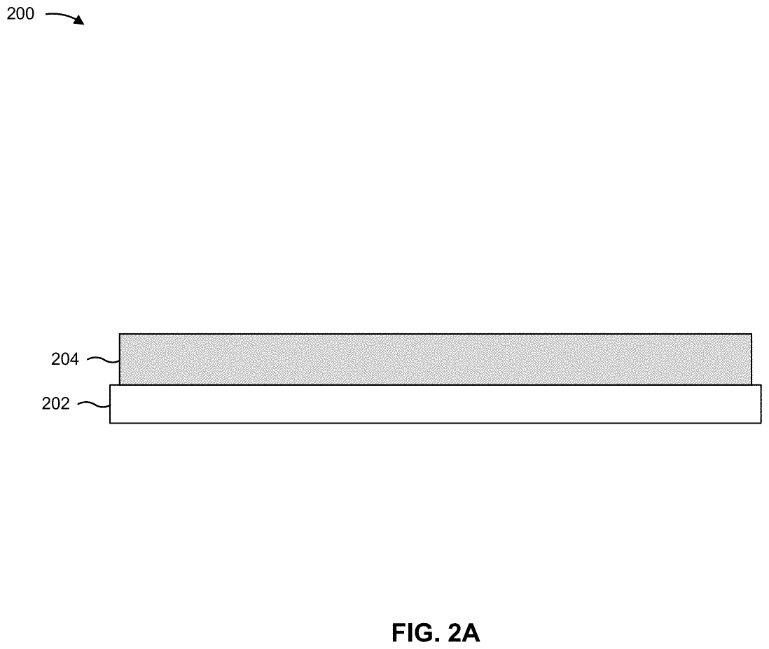

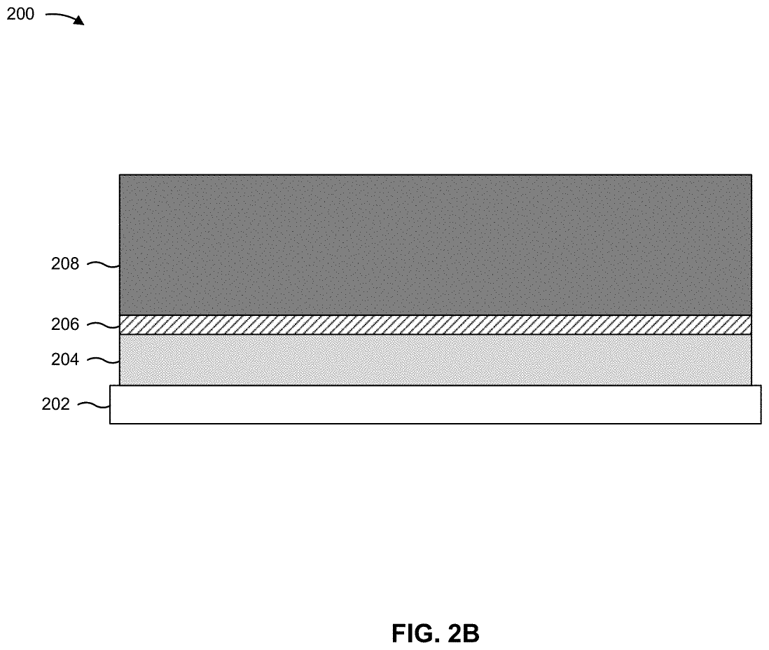

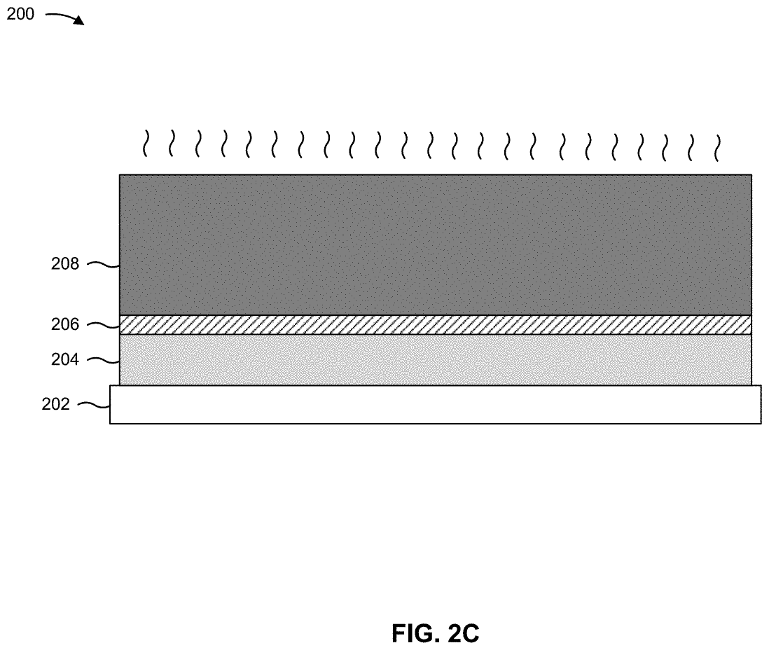

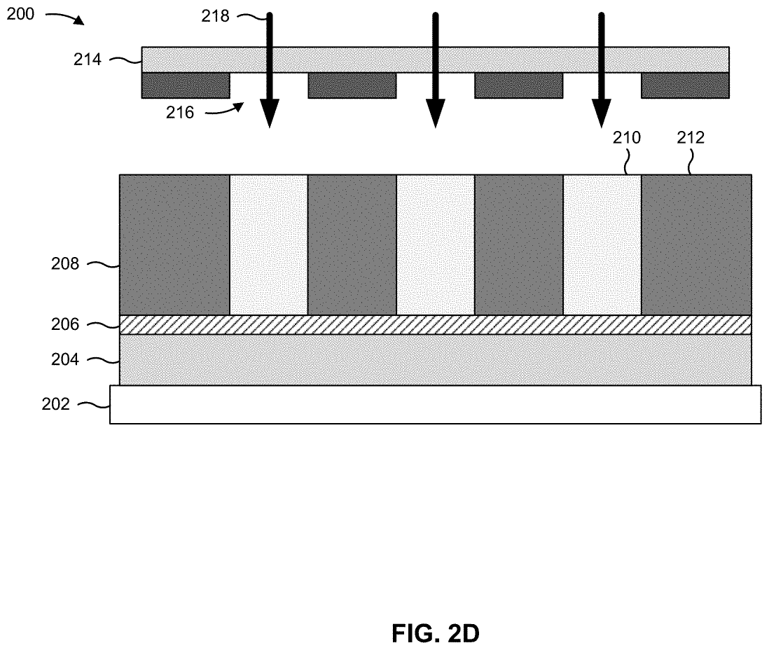

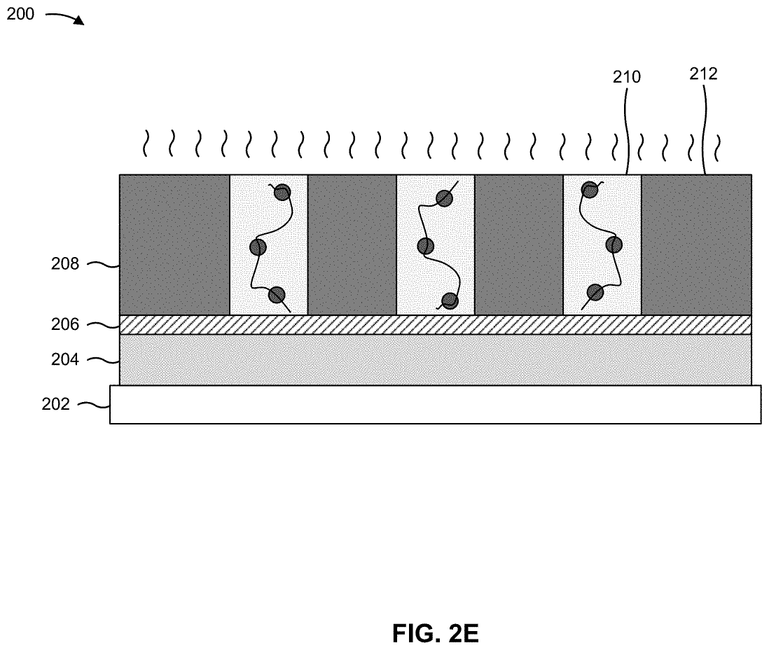

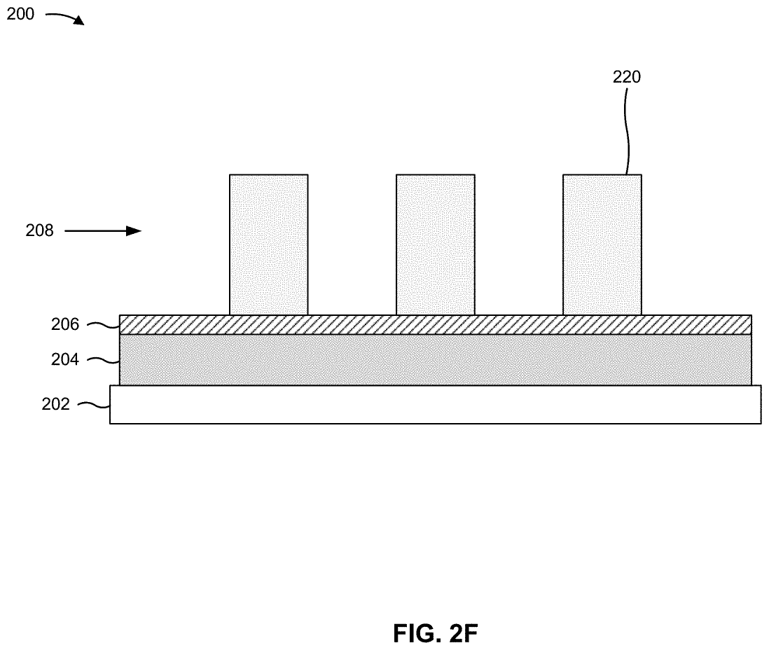

FIGS. 2A-2F are diagrams of an example implementation 200 described herein. The example implementation 200 may include an example of forming a pattern in a photoresist layer over a substrate using one or more of the photoresist materials described herein.

Turning to FIG. 2A, the substrate 202 may include a semiconductor die substrate, a semiconductor wafer, or another type of substrate in and/or on which semiconductor devices may be formed. In some implementations, the substrate 202 is formed of silicon (Si), a material including silicon, a III-V compound semiconductor material such as gallium arsenide (GaAs), a silicon on insulator (SOI), or another type of semiconductor material.

A layer 204 may be formed over and/or on the substrate 202. The layer 204 may be a layer that is to be etched based on a pattern in a photoresist layer. The layer 204 may be etched to form various types of semiconductor devices, openings, trenches, vias, interconnects, contacts, and/or other types of semiconductor structures. The layer 204 may include a dielectric layer, a metallization layer, a hard mask layer, and/or another type of semiconductor layer. In some implementations, the layer 204 is omitted, and the pattern is used to etch the substrate 202.

As shown in FIG. 2B, one or more layers may be formed over the substrate 204 in preparation for a first etch operation, such as an antireflective coating (ARC) 206 and a photoresist layer 208. The deposition tool 102 may deposit the ARC 206 using various PVD techniques, CVD techniques and/or ALD techniques, such as sputtering, PECVD, HDP-CVD, SACVD, and/or PEALD, among other examples. The deposition tool 102 may form the ARC 206 to a thickness of approximately 600 angstroms to approximately 800 angstroms based on one or more etching parameters for etching the layer 204 such as a target depth and/or a target width for the trenches or openings that are to be etched into the layer 204. However, other values for the thickness of the ARC 206 are within the scope of the present disclosure.

The photoresist layer 208 may include one or more of the photoresist materials described herein, such as a tin-based photoresist material or a tin oxide-based photoresist material. The photoresist material(s) that is used to form the photoresist layer 208 may include one or more types of tin (Sn) clusters, and a plurality of different types of carboxylate ligands or a plurality of carbonate ligands. The combination of the tin clusters and the plurality of different types of carboxylate ligands or a plurality of carbonate ligands may reduce, minimize, and/or prevent crystallization of the photoresist material used to form the photoresist layer 208, which may increase the coating performance of the photoresist material and may decrease the surface roughness of photoresist layer 208. The decreased surface roughness may reduce and/or minimize blurring and broken pattern lines in the pattern that is to be formed in the photoresist layer 208, and may enable decreases in half pitch sizes of the pattern that is to be formed in the photoresist layer 208, among other examples.

The deposition tool 102 may deposit the photoresist material using a deposition technique, such as a spin-coating technique, to form the photoresist layer 208. The deposition tool 102 may spin the substrate 202 at a spin rate in a range of approximately 800 revolutions per minute (RPM) to approximately 2200 RPM and for a time duration in a range of approximately 10 seconds to approximately 1 minute to ensure that the photoresist material is fully distributed across the surface of the ARC 206. However, other values for the spin rate and for the time duration are within the scope of the present disclosure.

The deposition tool 102 may form the photoresist layer 208 to a thickness of approximately 20 nanometers to approximately 30 nanometers to achieve a low surface roughness, to reduce and/or minimize blurring and broken pattern lines, to achieve a half pitch of the pattern that is to be formed in the photoresist layer 208 in a range of approximately 35 nanometers to approximately 18 nanometers or lower, and/or to achieve a low radiation dosage energy in a range of approximately 180 milli-Joules per centimeter area to approximately 150 mJ/cm² or lower. However, other values for the thickness of the photoresist layer 208 are in within the scope of the present disclosure.

As shown in FIG. 2C, a pre-exposure bake operation may be performed on the photoresist layer 208. A pre-exposure bake (or soft bake) operation may include a baking operation that is performed prior to exposure of a photoresist layer 208 on the substrate 202 to radiation by the exposure tool 104. The pre-exposure bake operation may be performed to evaporate a solvent that is mixed with the photoresist material. The photoresist material may be mixed with a solvent, such as 2-methylpentan-1-ol, 4-methylpentan-1-ol, or another photoresist solvent to facilitate the distribution of photoresist material across the substrate 202 in a spin coating operation to form the photoresist layer 208. The pre-exposure bake operation may promote the solidification of the photoresist material into the photoresist layer 208.

One or more of the deposition tool 102, the exposure tool 104, or an integrated tool that includes the deposition tool 102 and the exposure tool 104 may perform the pre-exposure bake operation. In some implementations, the pre-exposure bake operation is performed for a time duration that is in a range of approximately 30 seconds to approximately 600 seconds to ensure that the photoresist layer 208 is fully baked (and the solvent is fully removed) without unduly reducing throughput of photoresist pattern formation. However, other values for the time duration are within the scope of the present disclosure. In some implementations, the pre-exposure bake operation is performed at a temperature that is in a range of approximately 65 degrees Celsius to approximately 200 degrees Celsius to ensure that the solvent is removed from the photoresist material while reducing and/or minimizing metal cluster cross-linking in the photoresist layer 208 (which might lead to a reduction in resolution between exposed and unexposed portions of the photoresist layer 208). However, other values for the temperature are within the scope of the present disclosure.

As shown in FIG. 2D, an exposure operation may be performed on the photoresist layer 208 to form exposed portions 210 and unexposed portions 212 in the photoresist layer 208. The exposure operation may be performed by the exposure tool 104. The exposure tool 104 may include a mask (or reticle) 214 on which a pattern 216 is included. The exposure tool 104 may also include a radiation source that generates radiation 218. The exposed portions 210 are portions of the photoresist layer 208 that are exposed to the radiation 218. The unexposed portions 212 are portions of the photoresist layer 208 that are not exposed to the radiation 218.

In some implementations, the radiation 218 is transmitted through the mask 214 and onto the photoresist layer 208 based on the pattern 216. In some implementations, the radiation 218 includes EUV radiation, and the radiation 218 is reflected off of the mask 214 and onto the photoresist layer 208 based on the pattern 216. The wavelength of the radiation 218 may be in a range of approximately 0.005 nanometers to approximately 250 nanometers. Accordingly, the radiation 218 may include e-beam radiation (which may be used to directly expose the photoresist layer 208 without the use of a mask or reticle), EUV radiation, or deep UV radiation, among other examples.

As shown in FIG. 2E, one or more post-exposure bake operations may be performed on the photoresist layer 208 after exposure of the photoresist layer 208 to the radiation 218. The post-exposure bake operation(s) may be performed to promoted cross-linking of the photoresist material in the exposed portions 210 of the photoresist layer 208, as shown in FIG. 2E. In some implementations, a plurality of post-exposure bake operations may be performed such that a first post-exposure bake operation is performed and a second post-exposure bake operation is performed after the first post-exposure bake operation. The temperature of the second post-exposure bake operation may be greater relative to the temperature of the first post-exposure operation. In this way, performing a plurality of post-exposure bake operations enables precise control over the temperature ramping of the post-exposure bake of the photoresist layer 208.

One or more of the deposition tool 102, the exposure tool 104, the developer tool 106, or an integrated tool that includes the deposition tool 102, the exposure tool 104, and/or the developer tool 106 may perform the post-exposure bake operation(s). In some implementations, each post-exposure bake operation is performed for a time duration that is in a range of approximately 60 seconds to approximately 600 seconds to ensure sufficient cross-linking density in the exposed portions 210 of the photoresist layer 208 without causing over cross-linking (which may lead to an increased amount of photoresist residue remaining on the substrate 202 after a development operation). However, other values for the time duration for each post-exposure bake operation are within the scope of the present disclosure.

In some implementations, a post-exposure bake operation may be performed at a temperature that is in a range of approximately 90 degrees Celsius to approximately 250 degrees Celsius to ensure sufficient cross-linking density in the exposed portions 210 of the photoresist layer 208 without causing over cross-linking. In implementations where a plurality of post-exposure bake operations are performed, a first post-exposure bake operation may be performed at a temperature that is in a range of approximately 130 degrees Celsius to approximately 220 degrees Celsius, and a second post-exposure bake operation may be performed at a temperature that is in a range of approximately 160 degrees Celsius to approximately 250 degrees Celsius, to ensure sufficient cross-linking density in the exposed portions 210 of the photoresist layer 208 without causing over cross-linking. However, other values for the temperatures of the post-exposure operations are within the scope of the present disclosure.

As shown in FIG. 2F, a pattern 220 may be developed in the photoresist layer 208 after the exposure operation and the one or more post-exposure bake operations. The developer tool 106 may perform a development operation to develop the pattern 220 based on the exposed portions 210 and the unexposed portions 212. The time duration of the development operation may range from approximately 30 seconds to approximately 60 seconds. However, other values for the time duration are within the scope of the present disclosure. The photoresist material used for the photoresist layer 208 may be a metallic negative photoresist material that includes one or more types of tin (Sn) clusters and a plurality of types of organic ligands (e.g., carboxylate ligands) or inorganic ligands (e.g., carbonate ligands). Accordingly, the developer tool 106 may use a developer (or developer agent) to remove the unexposed portions 212, thereby leaving the exposed portions 210 behind as the pattern 220. The developer tool 106 may use various types of developers, such as 2-Heptanone and/or another type of developer. After the development operation is performed, the pattern 220 may be used in a subsequent semiconductor processing operation, which may include etching the layer 204 and/or the substrate 202, implanting ions into the layer 204 and/or the substrate 202, patterning the layer 204 as a hard mask, and/or another type of semiconductor processing operation.

As indicated above, FIGS. 2A-2F are provided as an example. Other examples may differ from what is described with regard to FIGS. 2A-2F.

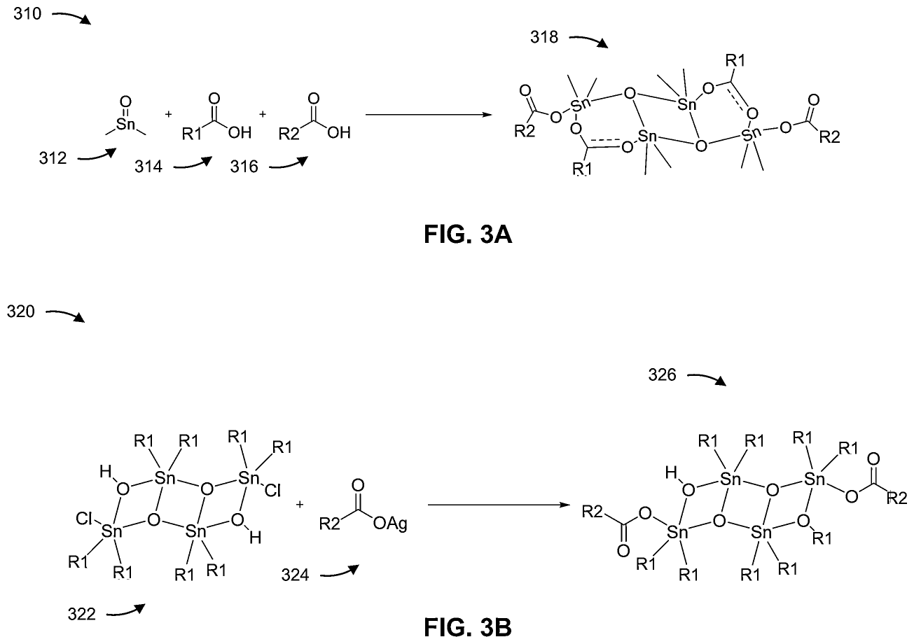

FIGS. 3A and 3B are diagrams of example photoresist material reactions described herein. The example photoresist material reactions may be performed to form photoresist materials that may be used in various semiconductor processing operations described herein, such as the semiconductor processing operations described above in connection with FIGS. 2A-2F. In particular, the example photoresist material reactions described in connection with FIGS. 3A and 3B may be performed to form photoresist materials that may be used to form the photoresist layer 208. The example photoresist material reactions described in connection with FIGS. 3A and 3B may be performed to form photoresist materials that include a plurality of tin (Sn) clusters bearing two or more types of organic carboxylate ligands. Including two or more types of carboxylate ligands along with the tin clusters may reduce, minimize, and/or prevent crystallization of the photoresist materials, which may increase the coating performance of the photoresist materials and may decrease the surface roughness of the photoresist layer 208.

FIG. 3A illustrates an example photoresist material reaction 310. As shown in FIG. 3A, the example photoresist material reaction 310 may include a tin (Sn) cluster 312, a first carboxylic acid 314, and a second carboxylic acid 316. The reaction between the tin cluster 312, the first carboxylic acid 314, and the second carboxylic acid 316 may include a reflux reaction, in which the constituents (e.g., the tin cluster 312, the first carboxylic acid 314, and the second carboxylic acid 316) are heated for a time duration (e.g., to approximately 110 degrees Celsius or another temperature for approximately 8 hours or another time duration). The heating of the constituents causes the formation of a vapor, which is continually cooled back into liquid form (e.g., as condensation) using a condenser. The condensate of the vapor is returned back to the original reaction chamber to continually undergo the above-described process for the time duration to distill the reaction. The constituents may be refluxed with toluene or one or more other assisting chemicals. The reflux reaction may result in the formation of the photoresist material 318 illustrated in FIG. 3A.

The tin cluster (or tin oxide (SnOₓ) cluster) 312 may include a collection of tin (or tin oxide) atoms ranging from 3-tin to 12-tin. For example, the tin cluster 312 may include a 3-tin cluster, a 4-tin cluster, a 6-tin cluster, a 10-tin cluster, a 12-tin cluster, or another tin cluster. Generally, the lower the cluster number, the smaller the cluster size. As an example, a 4-tin cluster may range from approximately 0.4 nanometers in size to approximately 1 nanometer in size, whereas a 6-tin cluster may range from approximately 0.6 nanometers in size to approximately 1 nanometer in size. The line width roughness (LWR) performance of the photoresist material 318 may increase the smaller the cluster size of the tin cluster 312. However, smaller cluster sizes may provide fewer cross-linking sites and fewer ligand sites, which may result in increased radiation exposure for patterning a photoresist layer formed using the photoresist material 318. In some implementations, a single tin cluster number is used to form the photoresist material 318. In some implementations, a plurality of different tin cluster numbers are used to form the photoresist material 318.

As further shown in FIG. 3A, the first carboxylic acid 314 and the second carboxylic acid 316 may be different types of carboxylic acids. The first carboxylic acid 314 and the second carboxylic acid 316 may include different R substituents—as shown, R1 in the first carboxylic acid 314 and R2 in the second carboxylic acid 316. Examples of carboxylic acids that may be used for the first carboxylic acid 314 or the second carboxylic acid 316 include formic acid, acetic acid, propionic acid, butyric acid, and/or another type of carboxylic acid including a carbon atom count ranging from 1 carbon atom (C1) to 20 carbon atoms (C2) or greater. In this way, the reflux reaction results in the photoresist material 318 including different types of carboxylate ligands (e.g., a first type of carboxylate ligand including the R1 substituent of the first carboxylic acid 314 and a second type of carboxylate ligand including the R2 substituent of the carboxylic acid 316). In addition to decreasing crystallization of the photoresist material 318, the different types of carboxylate ligands may enable increased tin density in a range of approximately 2.2 milligrams per cubic meter (mg/m³) to approximately 2.4 mg/m³ or greater. The increased tin density increases the EUV absorption capability of the photoresist material 318, which enables the photoresist material 318 to be used with lower radiation exposure doses while still achieving good patterning performance.

FIG. 3B illustrates an example photoresist material reaction 320. The example photoresist material reaction 320 may include a precipitation reaction to form a photoresist material including tin (Sn) clusters bearing two or more types of carboxylate ligands. As shown in FIG. 3B, the example photoresist material reaction 320 may include a compound 322 and a silver (Ag) salt 324 of a first carboxylic acid. The compound 322 may include one or more tin (Sn) clusters or tin oxide (SnOₓ) clusters, such as a 3-tin cluster, a 4-tin cluster, a 6-tin cluster, a 10-tin cluster, a 12-tin cluster, or another tin cluster. The compound 322 may also include chlorine (Cl), a second carboxylic acid including hydroxyl (—OH), and a substituent R1 including isopropyl or n-butyl, among other examples. The silver salt 324 may include a substituent R2, which may be different from the second carboxylic acid.

The precipitation reaction may include a reflux, in which the constituents (e.g., the compound 322 and the silver salt 324) are heated for a time duration (e.g., to approximately 110 degrees Celsius or another temperature for approximately 8 hours or another time duration). The heating of the constituents causes the formation of a vapor, which is continually cooled back into liquid form (e.g., as condensation) using a condenser. The condensate of the vapor is returned back to the original reaction chamber to continually undergo the above-described process for the time duration to distill the reaction. The constituents may be refluxed with dichloromethane (DCM), tetrahydrofuran (THF), or one or more other assisting chemicals. The reflux reaction may result in the formation of the photoresist material 326 illustrated in FIG. 3B. During the precipitation reaction, the chlorine of the compound 322 is exchanged with the carboxylic acid of the silver salt 324, thereby forming the photoresist material 326. This exchange results in the formation of the precipitant silver chloride (AgCl), which is removed from the reaction as a byproduct.

As indicated above, FIGS. 3A and 3B are provided as examples. Other examples may differ from what is described with regard to FIGS. 3A and 3B.

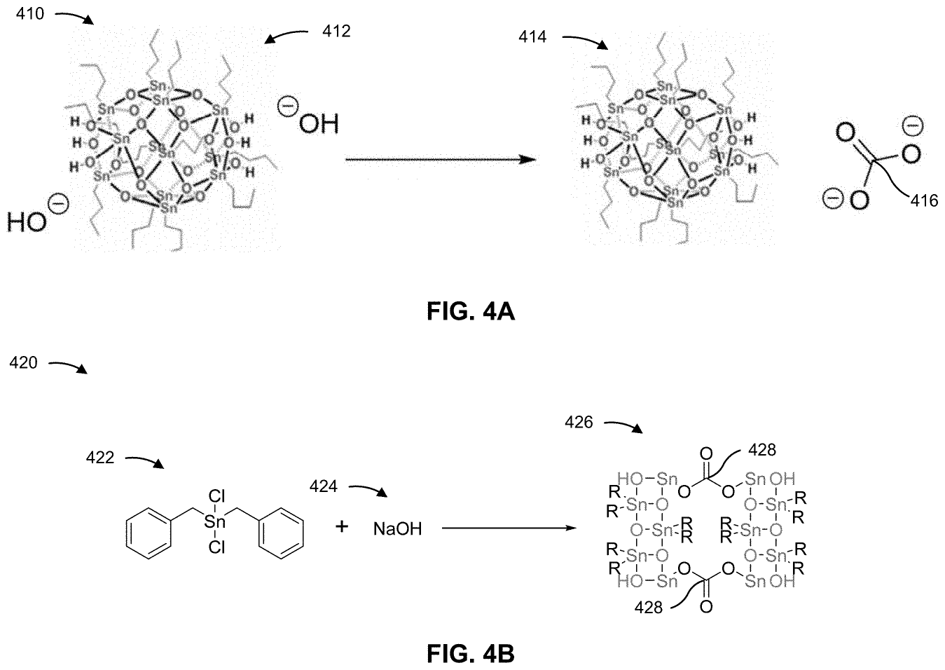

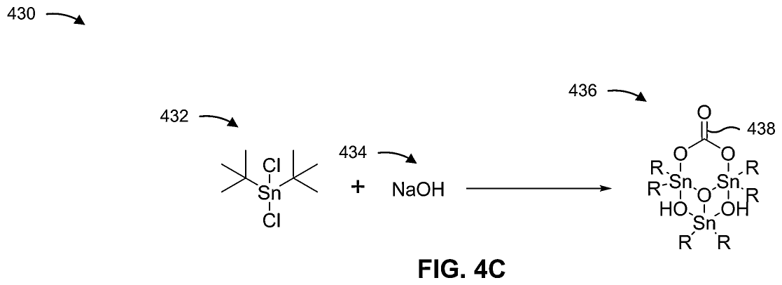

FIGS. 4A-4C are diagrams of example photoresist material reactions described herein. The example photoresist material reactions may be performed to form photoresist materials that may be used in various semiconductor processing operations described herein, such as the semiconductor processing operations described above in connection with FIGS. 2A-2F. In particular, the example photoresist material reactions described in connection with FIGS. 4A-4C may be performed to form photoresist materials that may be used to form the photoresist layer 208. The example photoresist material reactions described in connection with FIGS. 4A-4C may be performed to form photoresist materials that include a plurality of tin oxide (SnOₓ) clusters bearing inorganic carbonate (CO₃) ligands. The carbonate ligands along with the tin oxide clusters may reduce, minimize, and/or prevent crystallization of the photoresist materials, which may increase the coating performance of the photoresist materials and may decrease the surface roughness of the photoresist layer 208. Moreover, the carbonate ligands may be unstable during exposure of the photoresist layer 208. The instability may enable the use of lower radiation exposure energy levels when pattering the photoresist layer 208.

As shown in FIG. 4A, an example photoresist material reaction 410 may include a tin oxide (SnOₓ) cluster 412 such as a 12-tin oxide cluster. The example photoresist material reaction 410 includes a room temperature reaction in which carbon dioxide (CO₂) and a dicarboxylic acid such as oxalic acid or another dicarboxylic acid react with the tin oxide cluster 412. The reaction results in the formation of a photoresist material 414 that includes the tin oxide cluster 412 and a carbonate ligand 416.

As shown in FIG. 4B, an example photoresist material reaction 420 may include a compound 422 and sodium hydroxide (NaOH or lye) 424. The compound 422 may include a tin (Sn) cluster such as a 10-tin cluster. The compound 422 may also include chlorine (Cl). The example photoresist material reaction 420 includes a reflux reaction in which carbon dioxide (CO₂) and ethanol (EtOH) react with the compound 422 and the sodium hydroxide 424. The reaction results in the exchange of the chlorine in the compound 422 with the hydroxyl of the sodium hydroxide 424, which results in the formation of the precipitant sodium chloride (NaCl). The reflux reaction may be performed at an elevated temperature for a time duration of approximately 12 hours or another time duration. The reflux reaction may result in the formation of a photoresist material 426 that includes 10-tin oxide clusters (e.g., resulting from the precipitation of the chlorine and the sodium), a carbonate ligand 428, and a substituent such as benzyl or another type of substituent.

As shown in FIG. 4C, an example photoresist material reaction 430 may include a compound 432 and sodium hydroxide (NaOH or lye) 434. The compound 422 may include a tin (Sn) cluster such as a 3-tin cluster. The compound may also include chlorine (Cl). The example photoresist material reaction 430 includes a reflux reaction in which carbon dioxide (CO₂) and ethanol (EtOH) react with the compound 432 and the sodium hydroxide 434. The reaction results in the exchange of the chlorine in the compound 432 with the hydroxyl of the sodium hydroxide 434, which results in the formation of the precipitant sodium chloride (NaCl). The reflux reaction may be performed at an elevated temperature for a time duration of approximately 12 hours or another time duration. The reflux reaction may result in the formation of a photoresist material 436 that includes 3-tin oxide clusters (e.g., resulting from the precipitation of the chlorine and the sodium), a carbonate ligand 438, and a substituent such as benzyl or another type of substituent.

As indicated above, FIGS. 4A-4C are provided as examples. Other examples may differ from what is described with regard to FIGS. 4A-4C.

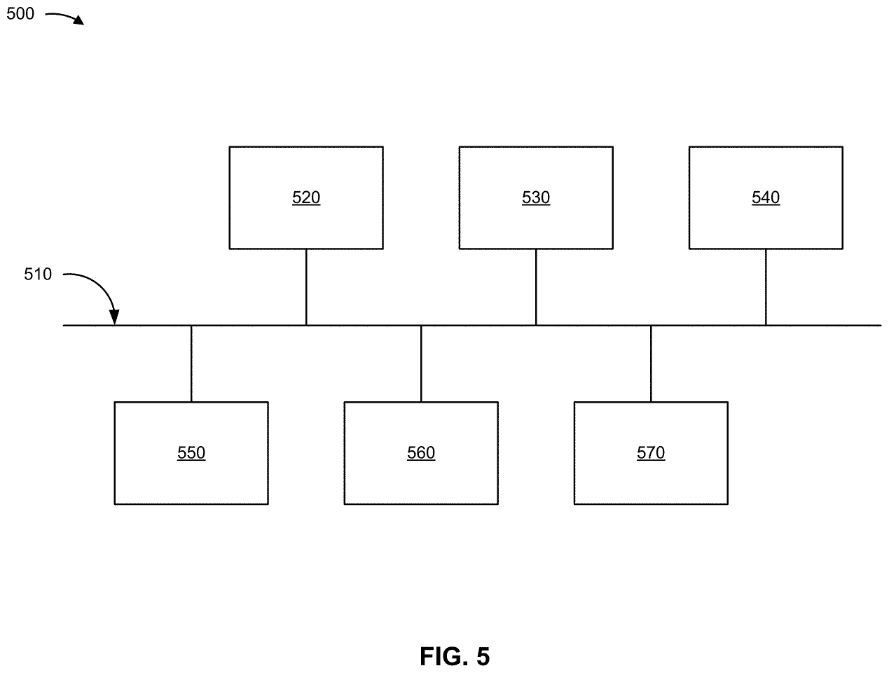

FIG. 5 is a diagram of example components of a device 500. In some implementations, the one or more semiconductor processing tools 102-108 and/or the wafer/die transport tool 110 may include one or more devices 500 and/or one or more components of device 500. As shown in FIG. 5, device 500 may include a bus 510, a processor 520, a memory 530, a storage component 540, an input component 550, an output component 560, and a communication component 570.

Bus 510 includes a component that enables wired and/or wireless communication among the components of device 500. Processor 520 includes a central processing unit, a graphics processing unit, a microprocessor, a controller, a microcontroller, a digital signal processor, a field-programmable gate array, an application-specific integrated circuit, and/or another type of processing component. Processor 520 is implemented in hardware, firmware, or a combination of hardware and software. In some implementations, processor 520 includes one or more processors capable of being programmed to perform a function. Memory 530 includes a random access memory, a read only memory, and/or another type of memory (e.g., a flash memory, a magnetic memory, and/or an optical memory).

Storage component 540 stores information and/or software related to the operation of device 500. For example, storage component 540 may include a hard disk drive, a magnetic disk drive, an optical disk drive, a solid state disk drive, a compact disc, a digital versatile disc, and/or another type of non-transitory computer-readable medium. Input component 550 enables device 500 to receive input, such as user input and/or sensed inputs. For example, input component 550 may include a touch screen, a keyboard, a keypad, a mouse, a button, a microphone, a switch, a sensor, a global positioning system component, an accelerometer, a gyroscope, and/or an actuator. Output component 560 enables device 500 to provide output, such as via a display, a speaker, and/or one or more light-emitting diodes. Communication component 570 enables device 500 to communicate with other devices, such as via a wired connection and/or a wireless connection. For example, communication component 570 may include a receiver, a transmitter, a transceiver, a modem, a network interface card, and/or an antenna.

Device 500 may perform one or more processes described herein. For example, a non-transitory computer-readable medium (e.g., memory 530 and/or storage component 540) may store a set of instructions (e.g., one or more instructions, code, software code, and/or program code) for execution by processor 520. Processor 520 may execute the set of instructions to perform one or more processes described herein. In some implementations, execution of the set of instructions, by one or more processors 520, causes the one or more processors 520 and/or the device 500 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 5 are provided as an example. Device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

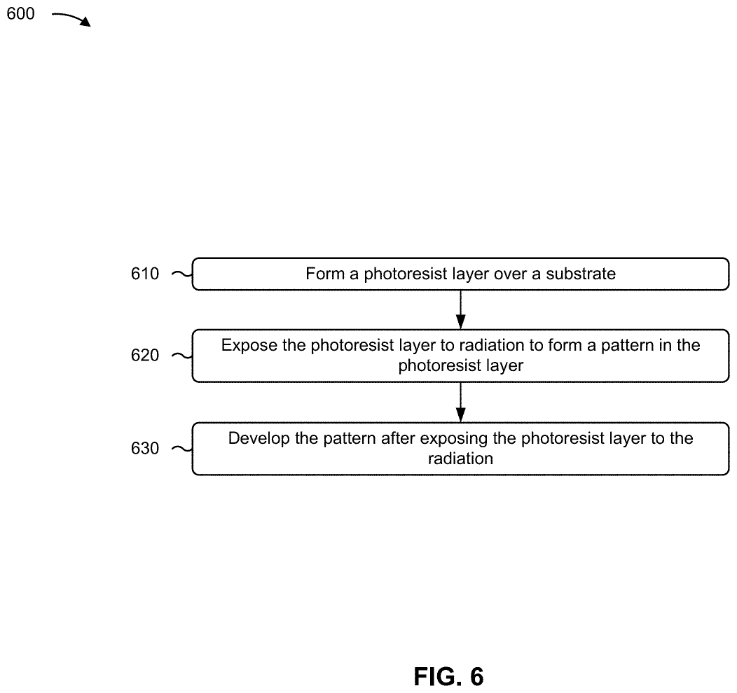

FIG. 6 is a flowchart of an example process 600 associated with forming a pattern in a photoresist layer. In some implementations, one or more process blocks of FIG. 6 may be performed by one or more semiconductor processing tools (e.g., one or more of the semiconductor processing tools 102-108). Additionally, or alternatively, one or more process blocks of FIG. 6 may be performed by one or more components of device 500, such as processor 520, memory 530, storage component 540, input component 550, output component 560, and/or communication component 570.

As shown in FIG. 6, process 600 may include forming a photoresist layer over a substrate (block 610). For example, the deposition tool 102 may form the photoresist layer 208 over the substrate 202, as described above. In some implementations, a photoresist material (e.g., the photoresist material 318, 326, 414, 426, and/or 436), that is used to form the photoresist layer 208, includes a plurality of tin clusters (e.g., tin cluster 312, tin clusters included in the compound 322, tin oxide cluster 412, tin clusters included in the compound 422, and/or tin clusters included in the compound 432) and at least one of a plurality of different types of organic ligands (e.g., carboxyl ligands R1 and/or R2) or a plurality of inorganic ligands (e.g., e.g., carbonate ligands 416, 428, and/or 438).

As further shown in FIG. 6, process 600 may include exposing the photoresist layer to radiation to form a pattern in the photoresist layer (block 620). For example, the exposure tool 104 may expose the photoresist layer to the radiation 218 to form the pattern 220 in the photoresist layer, as described above.

As further shown in FIG. 6, process 600 may include developing the pattern after exposing the photoresist layer to the radiation (block 630). For example, the developer tool 106 may develop the pattern after exposing the photoresist layer to the radiation, as described above.

Process 600 may include additional implementations, such as any single implementation or any combination of implementations described below and/or in connection with one or more other processes described elsewhere herein.

In a first implementation, the radiation includes EUV radiation. In a second implementation, alone or in combination with the first implementation, process 600 includes performing (e.g., by the deposition tool 102, the exposure tool 104, and/or another semiconductor processing tool), prior to exposing the photoresist layer 208 to the radiation 218, a pre-exposure bake of the photoresist layer 208 for a duration that is in a range of approximately 30 seconds to approximately 600 seconds. In a third implementation, alone or in combination with one or more of the first and second implementations, process 600 includes performing (e.g., by the deposition tool 102, the exposure tool 104, and/or another semiconductor processing tool), prior to exposing the photoresist layer 208 to the radiation 218, a pre-exposure bake of the photoresist layer 208 at a temperature that is in a range of approximately 65 degrees Celsius to approximately 200 degrees Celsius.

In a fourth implementation, alone or in combination with one or more of the first through third implementations, process 600 includes performing (e.g., by the exposure tool 104, the developer tool 106, and/or another semiconductor processing tool), after exposing the photoresist layer 208 to the radiation 218 and prior to developing the pattern, a post-exposure bake of the photoresist layer 208 for a duration that is in a range of approximately 60 seconds to approximately 600 seconds. In a fifth implementation, alone or in combination with one or more of the first through fourth implementations, process 600 includes performing (e.g., by the exposure tool 104, the developer tool 106, and/or another semiconductor processing tool), after exposing the photoresist layer 208 to the radiation 218 and prior to developing the pattern, a post-exposure bake of the photoresist layer 208 at a temperature that is in a range of approximately 90 degrees Celsius to approximately 250 degrees Celsius.

In a sixth implementation, alone or in combination with one or more of the first through fifth implementations, process 600 includes performing (e.g., by the exposure tool 104, the developer tool 106, and/or another semiconductor processing tool) a first post-exposure bake of the photoresist layer 208 after exposing the photoresist layer 208 to the radiation 218 and prior to developing the pattern 220, and performing (e.g., by the exposure tool 104, the developer tool 106, and/or another semiconductor processing tool) a second post-exposure bake of the photoresist layer 208 after the first post-exposure bake. In a seventh implementation, alone or in combination with one or more of the first through sixth implementations, a temperature of the second post-exposure bake is greater relative to a temperature of the first post-exposure bake.

In an eighth implementation, alone or in combination with one or more of the first through seventh implementations, a temperature of the first post-exposure bake is in a range of approximately 130 degrees Celsius to approximately 220 degrees Celsius, and a temperature of the second post-exposure bake is in a range of approximately 160 degrees Celsius to approximately 250 degrees Celsius. In a ninth implementation, alone or in combination with one or more of the first through eighth implementations, forming the photoresist layer 208 includes forming the photoresist layer 208 to a thickness in a range of approximately 20 nanometers to approximately 40 nanometers.

In a tenth implementation, alone or in combination with one or more of the first through ninth implementations, a wavelength of the radiation 218 is in a range of approximately 0.005 nanometers to approximately 250 nanometers. In an eleventh implementation, alone or in combination with one or more of the first through tenth implementations, the plurality of different types of organic ligands include a plurality of different types of carboxylic acids. In a twelfth implementation, alone or in combination with one or more of the first through eleventh implementations, the plurality of inorganic ligands include a plurality of carbonate ligands.

Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

In this way, photoresist materials described herein may include various types of tin (Sn) clusters having one or more types of ligands. As an example, a photoresist material described herein may include tin clusters bearing two or more different types of carboxylate ligands. As another example, a photoresist material described herein may include tin oxide clusters that include carbonate ligands. The two or more different types of carboxylate ligands and the carbonate ligands may reduce, minimize, and/or prevent crystallization of the photoresist materials described herein, which may increase the coating performance of the photoresist materials and may decrease the surface roughness of photoresist layers formed using the photoresist materials described herein.

As described in greater detail above, some implementations described herein provide a method. The method includes forming a photoresist layer over a substrate. A photoresist material, that is used to form the photoresist layer, includes a plurality of tin clusters and at least one of a plurality of different types of organic ligands or a plurality of inorganic ligands. The method includes exposing the photoresist layer to radiation to form a pattern in the photoresist layer. The method includes developing the pattern after exposing the photoresist layer to the radiation.

As described in greater detail above, some implementations described herein provide an EUV photoresist material. The EUV photoresist material includes a plurality of tin clusters. The EUV photoresist material includes a plurality of carboxylate ligands of the plurality of tin clusters, where the plurality of carboxylate ligands include two or more different types of carboxylic acids.

As described in greater detail above, some implementations described herein provide EUV photoresist material. The EUV photoresist material includes a plurality of tin oxide clusters. The EUV photoresist material includes a plurality of carbonate ligands of the plurality of tin oxide clusters.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method (600), comprising:
forming a photoresist layer (208) over a substrate (202),
wherein a photoresist material (318, 326, 414, 426, 436), that is used to form the photoresist layer, comprises:
a plurality of tin clusters (312, 322, 412, 422, 432), and
at least one of:
a plurality of different types of organic ligands (R1, R2), or
a plurality of inorganic ligands (416, 428, 438);
exposing the photoresist layer to radiation (218) to form a pattern (220) in the photoresist layer; and
developing the pattern after exposing the photoresist layer to the radiation.

2. The method of claim 1, wherein the radiation comprises extreme ultraviolet (EUV) radiation.

3. The method of claim 1, further comprising:
performing, prior to exposing the photoresist layer to the radiation, a pre-exposure bake of the photoresist layer for a duration that is in a range of approximately 30 seconds to approximately 600 seconds.

4. The method of claim 1, further comprising:
performing, prior to exposing the photoresist layer to the radiation, a pre-exposure bake of the photoresist layer at a temperature that is in a range of approximately 65 degrees Celsius to approximately 200 degrees Celsius.

5. The method of claim 1, further comprising:
performing, after exposing the photoresist layer to the radiation and prior to developing the pattern, a post-exposure bake of the photoresist layer for a duration that is in a range of approximately 60 seconds to approximately 600 seconds.

6. The method of claim 1, further comprising:
performing, after exposing the photoresist layer to the radiation and prior to developing the pattern, a post-exposure bake of the photoresist layer at a temperature that is in a range of approximately 90 degrees Celsius to approximately 250 degrees Celsius.

7. The method of claim 1, further comprising:
performing a first post-exposure bake of the photoresist layer after exposing the photoresist layer to the radiation and prior to developing the pattern; and
performing a second post-exposure bake of the photoresist layer after the first post-exposure bake.

8. The method of claim 7, wherein a temperature of the second post-exposure bake is greater relative to a temperature of the first post-exposure bake.

9. The method of claim 7, wherein a temperature of the first post-exposure bake is in a range of approximately 130 degrees Celsius to approximately 220 degrees Celsius; and
wherein a temperature of the second post-exposure bake is in a range of approximately 160 degrees Celsius to approximately 250 degrees Celsius.

10. The method of claim 1, wherein forming the photoresist layer comprises:
forming the photoresist layer to a thickness in a range of approximately 20 nanometers to approximately 40 nanometers.

11. The method of claim 1, wherein a wavelength of the radiation is in a range of approximately 0.005 nanometers to approximately 250 nanometers.

12. The method of claim 1, wherein the plurality of different types of organic ligands comprise a plurality of different types of carboxylic acids.

13. The method of claim 1, wherein the plurality of inorganic ligands comprise a plurality of carbonate ligands.

14. An extreme ultraviolet (EUV) photoresist material (318, 326), comprising:
a plurality of tin clusters (312, 322); and
a plurality of carboxylate ligands (R1, R2) of the plurality of tin clusters,
wherein the plurality of carboxylate ligands include two or more different types of carboxylic acids.

15. The EUV photoresist material of claim 14, wherein the two or more different types of carboxylic acids comprise formic acid and acetic acid.

16. The EUV photoresist material of claim 14, wherein the plurality of tin clusters comprise one or more of:
a plurality of 3-tin clusters,
a plurality of 4-tin clusters, or
a plurality of 10-tin clusters.

17. The EUV photoresist material of claim 14, wherein at least one of the two or more different types of carboxylic acids include a hydroxyl.

18. An extreme ultraviolet (EUV) photoresist material (414, 426, 436), comprising:
a plurality of tin oxide clusters (412, 422, 432); and
a plurality of carbonate ligands (416, 428, 438) of the plurality of tin oxide clusters.

19. The EUV photoresist material of claim 18, wherein the plurality of tin oxide clusters comprise one or more of:
a plurality of 3-tin clusters,
a plurality of 6-tin clusters, or
a plurality of 12-tin clusters.

20. The EUV photoresist material of claim 18, further comprising a benzyl.
